(19) United States
(12) Patent Application Publication
(10) Pub. No.: US 2025/0357299 A1
(43) Pub. Date: Nov. 20, 2025

(54) ARTIFICIAL INTELLIGENCE CHIP FOR MEMORY BANDWIDTH IMPROVEMENT

(71) Applicant: NEUCHIPS CORPORATION, Hsinchu City (TW)

(72) Inventors: Chih-Wei Chang, Hsinchu City (TW); Chu Wen Chen, Hsinchu City (TW); Tai Yu Chiu, Hsinchu County (TW); Ching Hua Hung, Taoyuan City (TW)

(73) Assignee: NEUCHIPS CORPORATION, Hsinchu City (TW)

(21) Appl. No.: 18/679,399

(22) Filed: May 30, 2024

(30) Foreign Application Priority Data
May 15, 2024 (TW) 113117868

(51) Int. Cl. H01L 23/498; H01L 23/00; H01L 25/065

(52) U.S. Cl. CPC H01L 23/49838; H01L 23/49816; H01L 24/08; H01L 24/48; H01L 25/0652; H01L 2224/08145; H01L 2224/08225; H01L 2224/48138; H01L 2224/48155; H01L 2924/1431; H01L 2924/1434; H01L 2924/15172; H01L 2924/15311

(57) ABSTRACT

An artificial intelligence (AI) chip includes a circuit substrate, a routing layer, and a system-on-chip (SOC). The routing layer is formed on a surface of the circuit substrate and includes multiple bump pads and multiple traces connecting SOC PHY bumps and substrate bumps. The disclosure utilizes advanced packaging to increase the number of signal lines, prompting appropriate changes in SOC planning to meet requirements of modern AI chips for high capacity and bandwidth, while effectively controlling costs. The SOC includes several DRAM interface physical structures (PHY), and the DRAM interface PHYs are electrically coupled to external devices through the routing layer to simultaneously receive signals from the external devices. The routing layer may be a fanout circuit layer.

### CROSS-REFERENCE TO RELATED APPLICATION

This application claims the priority benefit of Taiwan application serial no. 113117868, filed on May 15, 2024. The entirety of the above-mentioned patent application is hereby incorporated by reference herein and made a part of this specification.

### BACKGROUND

### Technical Field

The disclosure relates to an artificial intelligence (AI) chip, and more particularly, to an AI chip for memory bandwidth improvement.

### Description of Related Art

Due to characteristics of an AI chip, hundreds of gigabytes or even tens of terabytes of data are required to be processed. Such large amounts of data are stored in an external DRAM at the same time. When the data is moved from the external DRAM to a computing unit for processing, if a bandwidth is not enough, it will often become a performance bottleneck for an entire system. Therefore, regarding how to increase the bandwidth of the chip, in addition to selection of a manufacturing process, a high-speed interface is also the key to the success or failure of the chip.

Although there are currently complex connection packaging technologies (e.g., 2.5D CoWoS packaging) developed to solve an issue of bandwidths, this packaging technology is dozens of times more expensive than other packaging technologies, and a high-bandwidth (HBM) memory with 2.5D CoWoS package is also a high-cost device.

### SUMMARY

The disclosure provides an AI chip for memory bandwidth improvement, which uses a current advanced packaging technology to increase a DRAM bandwidth in a low-cost manner, so it may process a large number of signals at the same time, thereby improving a utilization rate of a computing element.

An artificial intelligence chip in the disclosure includes a circuit substrate, a routing layer, and a system-on-chip (SOC). The routing layer is formed on a surface of the circuit substrate and includes multiple bump pads and multiple traces, and the traces are disposed between the two adjacent bump pads. The system-on-chip is disposed on the surface of the circuit substrate. The system-on-chip includes multiple DRAM interface physical structures (PHY), and the DRAM interface physical structures are electrically coupled to multiple external devices through the routing layer to simultaneously receive signals from the external devices.

In an embodiment of the disclosure, a line width of the trace is less than 2 μm, and a spacing between the traces is less than 2 μm.

Another artificial intelligence chip in the disclosure includes a circuit substrate, a fanout circuit layer, and a system-on-chip (SOC). The fanout circuit layer is formed on a surface of the circuit substrate and includes multiple fanout lines. The system-on-chip is disposed on the surface of the circuit substrate. The system-on-chip includes multiple DRAM interface physical structures (PHY), and the DRAM interface physical structures are electrically coupled to multiple external devices through the fanout lines to simultaneously receive signals from the external devices.

In another embodiment of the disclosure, a line width of the fanout line is less than 2 μm, and a spacing between the fanout lines is less than 2 μm.

In another embodiment of the disclosure, the fanout circuit layer further includes multiple bump pads, and each of the bump pads is connected to one of the fanout lines.

In another embodiment of the disclosure, a number of the DRAM interface physical structures is 6, 8, 12, or 16.

In another embodiment of the disclosure, the external devices include double data rate (DDR) memory devices, graphic DDR (GDDR) memory devices, low power DDR (LPDDR) memory devices, or serializers/deserializers (SerDes).

In another embodiment of the disclosure, the circuit substrate includes a BT carrier board, an ABF carrier board, or an interposer.

Based on the above, the disclosure allows the AI chip to increase the bandwidth by placing more high-speed IO PHYs in a horizontal stacking manner and using a low-cost dense winding packaging method, thereby solving the bandwidth requirements of the AI chip.

In order for the aforementioned features and advantages of the disclosure to be more comprehensible, embodiments accompanied with drawings are described in detail below.

### BRIEF DESCRIPTION OF THE DRAWINGS

FIG. 1A is a schematic plan view of a packaging structure including an AI chip according to the first embodiment of the disclosure.

FIG. 1B is a schematic perspective view of the packaging structure in FIG. 1A.

FIG. 2 is a schematic enlarged view of a routing layer in the AI chip in FIG. 1A.

FIG. 3 is a schematic plan view of an AI chip according to the second embodiment of the disclosure.

FIG. 4 is a schematic plan view of an AI chip according to the third embodiment of the disclosure.

FIG. 5 is a schematic plan view of an AI chip according to the fourth embodiment of the disclosure.

### DETAILED DESCRIPTION OF DISCLOSED EMBODIMENTS

The disclosure below provides numerous different implementations or embodiments to describe different features of the disclosure. Moreover, these embodiments are merely exemplary and are not intended to limit the scope and application of the disclosure. At the same time, for the sake of clarity, the relative dimensions (such as length, thickness, pitch, etc.) and relative positions of each region, structure, or element may be reduced or enlarged. In addition, similar or the same reference numerals are used in each figure to represent similar or the same devices or features.

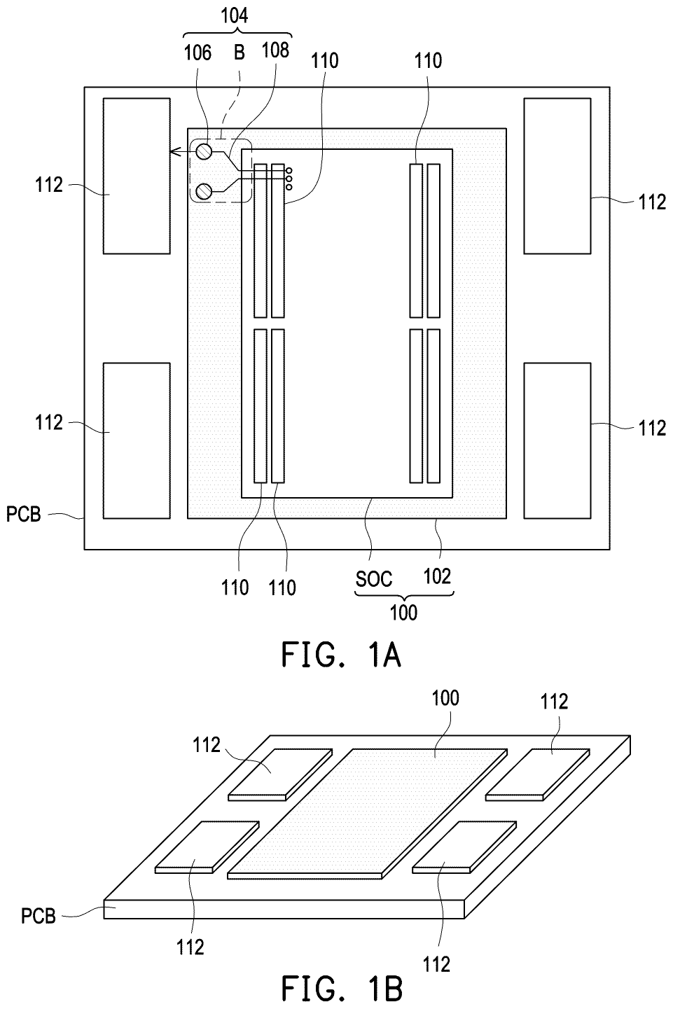

Stack planning similar to examples in FIGS. 1A, 3, 4, and 5 is basically used for an artificial intelligence chip in the disclosure in an initial floorplan of the chip to allow the chip to have more bandwidths to meet requirements for functions of the chip. Especially for the artificial intelligence chip that requires a large bandwidth, a memory interface wiring thereof is, for example, a low power double data rate (LPDDR) memory mentioned in the following embodiments, or other memories such as DDR, a graphic DDR (GDDR) memory, and a serializer/deserializer (SerDes), may all use the disclosure to increase the bandwidth, so that a bandwidth of a DRAM interface structure may be 1.5 times, 2 times, 3 times, or even 4 times of an original design.

FIG. 1A is a schematic plan view of a packaging structure including an AI chip according to the first embodiment of the disclosure. FIG. 1B is a schematic perspective view of the packaging structure in FIG. 1A, in which a structure of an AI chip 100 is simplified.

Referring to FIGS. 1A and 1B, the AI chip 100 in the first embodiment includes a circuit substrate 102, a routing layer 104, and a system-on-chip SOC. The AI chip 100 may be electrically coupled to an external device 112 through a circuit board PCB. The external device 112 is generally a memory, such as a double data rate (DDR) memory device, a graphic DDR (GDDR) memory device, a low power DDR (LPDDR) memory device, or a sequencer/deserializer (SerDes), but the disclosure is not limited thereto. A position and number of the external device 112 may also be adjusted or changed according to design requirements. In some embodiments, the circuit substrate 102 is, for example, a BT carrier board, an ABF carrier board, or an interposer, which may include multiple dielectric layers (not shown), circuits (not shown) embedded in each of the dielectric layers, and several conductive through-vias (not shown) formed in each of the dielectric layers and electrically connected to different circuits respectively.

Continuing to refer to FIG. 1A, the routing layer 104 is formed on a surface of the circuit substrate 102 and includes multiple bump pads 106 and multiple traces 108. Since the circuit substrate 102 may include the dielectric layers and circuits, a circuit design of the routing layer 104 is also applicable to the circuits in the circuit substrate 102. The system-on-chip SOC is also disposed on the surface of the circuit substrate 102. The system-on-chip SOC includes several DRAM interface physical structures (PHY) 110, and the number thereof is, for example, more than four. In some embodiments, the DRAM interface physical structure 110 may include a PHY layer and a controller, but the disclosure is not limited thereto. The DRAM interface physical structures 110 are electrically coupled to the external devices 112 through the routing layer 104 to simultaneously receive signals from the external devices 112. It is noted that since FIG. 1A is a schematic view, a ratio of the DRAM interface physical structure 110 to the system-on-chip SOC is not an actual ratio. In some embodiments, in addition to the DRAM interface physical structure 110, the system-on-chip SOC further includes a model architecture (e.g., a convolutional neural network (CNN)), an operator (e.g., GPU/CPU), a memory, an I/O interface (e.g., general-purpose input/output (GPIO), etc. to calculate and process a large amount of information input by the external device 112.

In the first embodiment, a computing element in the system-on-chip SOC may be connected to the external device 112 through a circuit in the circuit board PCB below by the bump pads 106 and traces 108 in the routing layer 104. The trace 108 may connect SOC PHY bumps (not shown) and substrate bumps (not shown). Moreover, the circuit board PCB may be further connected to other elements or devices that are not shown, and is not limited to the devices and components shown in FIG. 1A.

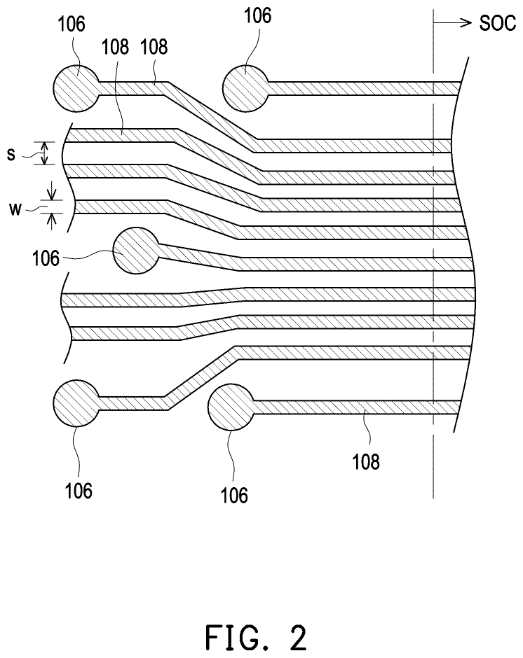

For the sake of clarity, only a portion of the routing layer 104 is shown in the schematic view of FIG. 1A. In fact, the routing layer 104 of the AI chip 100 is densely distributed throughout the AI chip 100. A detailed structure of the routing layer 104 may be referred to FIG. 2.

In FIG. 2, more than four traces 108 may be disposed between the two adjacent bump pads 106. Compared to an existing AI chip wiring with a line width/spacing of approximately 8 μm/8 μm, such design may increase routing resources by 4 times. For example, through a fanout semiconductor packaging process, a line width w of the formed trace 108 may be reduced to less than 2 μm, such as 2 μm or 1 μm, and a spacing s between the traces 108 may also be reduced to less than 2 μm, such as 2 μm or 1 μm. Therefore, the routing layer 104 may also be called a fanout circuit layer. The trace 108 may also be called a “fanout line”, and has a line width/spacing (w/s) of less than 2 μm. In addition, according to the circuit design, three or less traces 108 may be disposed between the two bump pads 106. A size of the bump pad 106 included in the fanout circuit layer may be similar to or smaller than that of an existing design. For example, a diameter of the circular bump pad 106 is about 100 μm to 200 μm, but the disclosure is not limited thereto. The above fanout semiconductor packaging process may include, but is not limited to, the following. First, the photoresist is patterned on the circuit substrate 102 through laser direct imaging (LDI) to form a patterned photoresist layer (not shown), and then the fanout lines (and the bump pads 106) are formed by electroplating. After the fanout lines are formed, the patterned photoresist layer may be removed.

As mentioned above, since the routing resources of the routing layer 104 are increased by 4 times, the number of traces 108 connected to the system-on-chip SOC is also greatly increased, thereby increasing the number of DRAM interface physical structures 110 in the AI chip 100. For example, the number of DRAM interface physical structures 110 in the first embodiment is eight. Compared to a previous AI chip that was limited by the trace width/spacing and the spacing between the adjacent bump pads, in which only the line width and spacing of 14 μm are allowed, resulting in only 1 or 2 traces passing through a middle of the bump pad, and since a large number of signal lines are required to be connected to the SOC, the number of layers of the circuit substrate 102 may only be increased, and more memory interfaces may not be placed, causing the bandwidth to limit the chip performance, in this embodiment, the fanout lines are used to reduce the original winding width and spacing, in which, for example, the winding width and spacing may reach 2 μm, which means that more signal lines may be utilized, thereby increasing the number of DRAM interface physical structures 110 from the original 4 to 8, for example, and a bandwidth of the AI chip 100 is doubled. Therefore, a large number of signals may be transmitted from the external device 112 (the memory) to the AI chip 100 for computation at the same time to solve bandwidth requirements of the AI chip 100, and there is no need to excessively increase the number of layers of the circuit substrate 102. In addition, the disclosure does not require a HBM memory used in a high-cost packaging structure, so it has a wider application range.

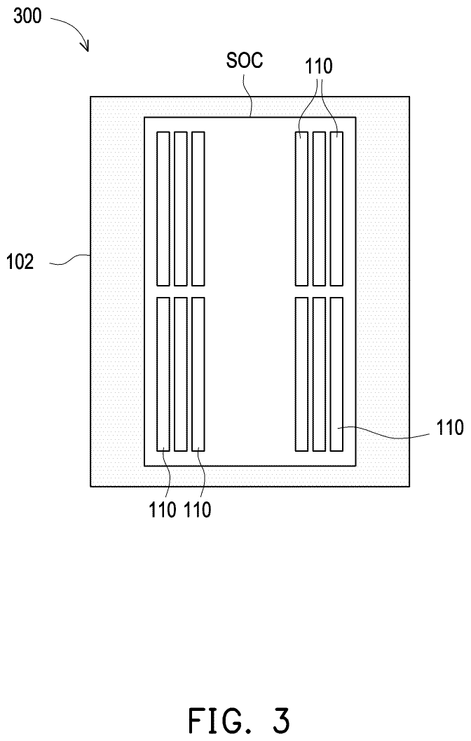

FIGS. 3, 4, and 5 are schematic plan views of an AI chip according to the second, third, and fourth embodiments of the disclosure. It is noted that since FIGS. 3, 4, and 5 are all schematic views, the ratio of the DRAM interface physical structure 110 to the system-on-chip SOC is not the actual ratio.

In FIG. 3, an AI chip 300 includes the circuit substrate 102 and the system-on-chip SOC. The routing layer therein may be referred to the first embodiment, and thus the same details will not be repeated in the following. The number of DRAM interface physical structures 110 included in the system-on-chip SOC is 12, so (based on the original four DRAM interface physical structures 110 as a comparison benchmark) the bandwidth is increased by three times. The DRAM interface physical structure 110 is, for example, a DDR interface, a GDDR interface, an LPDDR interface, or a SerDes interface, but the disclosure is not limited thereto. Since a memory stacking method provided in the disclosure is to stack inside the chip, it does not directly affect a length and width of the chip. For the AI chip that is often necessary to evaluate computility and balance between memory bandwidths, it is the most suitable way to increase the bandwidth.

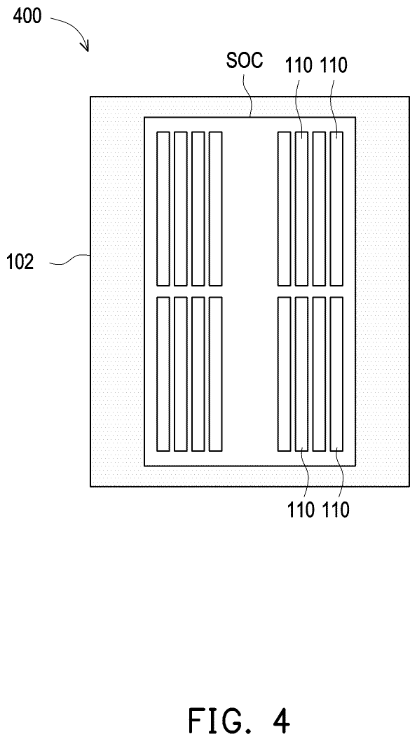

In FIG. 4, an AI chip 400 includes the circuit substrate 102 and the system-on-chip SOC. The routing layer therein may be referred to the first embodiment, and thus the same details will not be repeated in the following. The number of DRAM interface physical structures 110 included in the system-on-chip SOC is 16, so (based on the original four DRAM interface physical structures 110 as the comparison benchmark) the bandwidth is increased by four times. The DRAM interface physical structure 110 may also include the DDR interface, the GDDR interface, the LPDDR interface, or the SerDes interface, but the disclosure is not limited thereto.

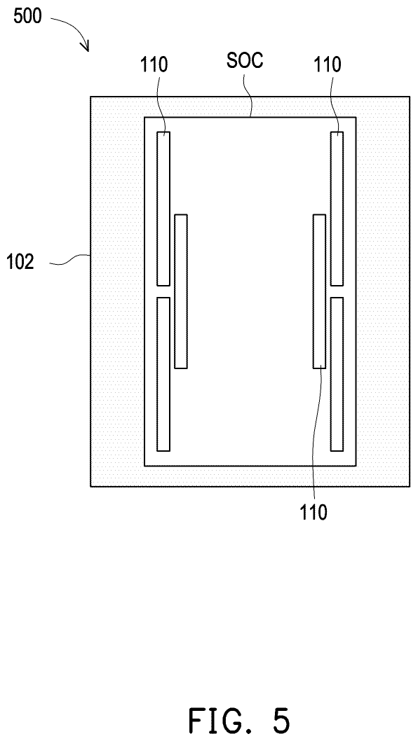

In FIG. 5, an AI chip 500 includes the circuit substrate 102 and the system-on-chip SOC. The routing layer therein may be referred to the first embodiment, and thus the same details will not be repeated in the following. The number of DRAM interface physical structures 110 included in the system-on-chip SOC is 6, so (based on the original four DRAM interface physical structures 110 as the comparison benchmark) the bandwidth is increased by 1.5 times. Positions of the six DRAM interface physical structures 110 in FIG. 5 are only exemplary, and are not intended to limit the positions of the DRAM interface physical structures 110 in the floorplan. Furthermore, since the number of DRAM interface physical structures 110 is less, the number of layers of the circuit substrate 102 may be reduced under the same routing resources. Therefore, not only the bandwidth is increased, but the substrate cost may also be reduced.

Based on the above, the specially designed routing layer is adopted on the surface of the circuit substrate in the disclosure, which may greatly increase the routing resources and increase the number of DRAM interface physical structures in the floorplan of the AI chip, thereby generating at least 1.5 times or even 2 times, 3 times, or 4 times the bandwidth, while taking into account cost control.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. An artificial intelligence chip, comprising:
a circuit substrate;
a routing layer formed on a surface of the circuit substrate, wherein the routing layer comprises a plurality of bump pads and a plurality of traces, and more than four of the traces are disposed between the two adjacent bump pads; and
a system-on-chip (SOC) disposed on the surface of the circuit substrate, wherein the system-on-chip comprises a plurality of DRAM interface physical structures (PHY), and the DRAM interface physical structures are electrically coupled to a plurality of external devices through the routing layer to simultaneously receive signals from the external devices.

2. The artificial intelligence chip according to claim 1, wherein a number of the DRAM interface physical structures is 6, 8, 12, or 16.

3. The artificial intelligence chip according to claim 1, wherein a line width of each of the traces is less than 2 μm, and a spacing between the traces is less than 2 μm.

4. The artificial intelligence chip according to claim 1, wherein the external devices comprise double data rate (DDR) memory devices, graphic DDR (GDDR) memory devices, low power DDR (LPDDR) memory devices, or serializers/deserializers (SerDes).

5. The artificial intelligence chip according to claim 1, wherein the circuit substrate comprises a BT carrier board, an ABF carrier board, or an interposer.

6. An artificial intelligence chip, comprising:
a circuit substrate;
a fanout circuit layer formed on a surface of the circuit substrate, wherein the fanout circuit layer comprises a plurality of fanout lines; and
a system-on-chip (SOC) disposed on the surface of the circuit substrate, wherein the system-on-chip comprises a plurality of DRAM interface physical structures (PHY), and the DRAM interface physical structures are electrically coupled to a plurality of external devices through the fanout lines to simultaneously receive signals from the external devices.

7. The artificial intelligence chip according to claim 6, wherein a number of the DRAM interface physical structures is 6, 8, 12, or 16.

8. The artificial intelligence chip according to claim 6, wherein a line width of each of the fanout lines is less than 2 μm, and a spacing between the fanout lines is less than 2 μm.

9. The artificial intelligence chip according to claim 6, wherein the external devices comprise double data rate (DDR) memory devices, graphic DDR (GDDR) memory devices, low power DDR (LPDDR) memory devices, or serializers/deserializers (SerDes).

10. The artificial intelligence chip according to claim 6, wherein the fanout circuit layer further comprises a plurality of bump pads, and each of the bump pads is connected to one of the fanout lines.

11. The artificial intelligence chip according to claim 6, wherein the circuit substrate comprises a BT carrier board, an ABF carrier board, or an interposer.
